(19) United States
(12) Patent Application Publication
(10) Pub. No.: US 2005/0141315 A1
(43) Pub. Date: Jun. 30, 2005

(54) System and method for adjusting noise

(76) Inventor: Tomoyuki Yoda, Saitama-shi (JP)

Correspondence Address: DLA PIPER RUDNICK GRAY CARY US, LLP, 2000 UNIVERSITY AVENUE, E. PALO ALTO, CA, 94303-2248, US

(21) Appl. No.: 10/838,722

(22) Filed: May 3, 2004

(30) Foreign Application Priority Data
Dec. 25, 2003 (JP) P2003-431195

(51) Int. Cl. G11C 8/00

(52) U.S. Cl. 365/223

(57) ABSTRACT

A system for adjusting noise includes a cell specification unit configured to specify a cell which transmits a cross talk noise to a receiver cell, a rise rate modification unit configured to slow down a rise rate of the cross talk noise, and a determination unit configured to determine a net connected to a output end of the cell as the net where the cross talk noise is reduced when the cross talk noise does not cause malfunction of the receiver cell and when a signal to be supplied to the receiver cell satisfies a timing constraint.

### CROSS REFERENCE TO RELATED APPLICATIONS

This application is based upon and claims the benefit of priority from the prior Japanese Patent Application No. P2003-431195, filed on Dec. 25, 2003; the entire contents of which are incorporated herein by reference.

### BACKGROUND OF THE INVENTION

1. Field of the Invention

The present invention relates to technology for adjusting noise automatically in an integrated circuit by use of computer, and specifically relates to system and method for adjusting noise.

2. Description of the Related Art

Because driving power of a low output impedance transistor is large, a signal waveform in an aggressor net from the low output impedance transistor causes large cross talk noise in a victim net. Because driving power of a high output impedance transistor is small, a signal waveform in the victim net from the high output impedance transistor is susceptible to cross talk noise. According to high density in an LSI, cross talk noise causes malfunction of a logic circuit.

In a conventional system and method for adjusting noise, capacitance in the victim net decreases by spacing between the aggressor net and the victim net or inserting repeater cells such as buffer cells or inverter cells in the victim net as shown in Japanese Patent Laid Open (Kokai) No.P2002-124572.

However, spacing between the aggressor net and the victim net leads to a large circuit design, thus increasing the circuit area. The cross talk noise may not decrease in spite of inserting the repeaters, thus shortening the length of the victim net and decreasing the capacitance. The repeater cells may not be inserted in the victim net in high density.

### SUMMARY OF THE INVENTION

An aspect of the present invention inheres in a system for adjusting noise including a cell specification unit configured to specify a cell which transmits a cross talk noise to a receiver cell, a rise rate modification unit configured to slow down a rise rate of the cross talk noise, and a determination unit configured to determine a net connected to a output end of the cell as the net where the cross talk noise is reduced when the cross talk noise does not cause malfunction of the receiver cell and when a signal to be supplied to the receiver cell satisfies a timing constraint.

An another aspect of the present invention inheres in a method for adjusting noise including specifying a cell which transmits a cross talk noise to a receiver cell, slowing down a rise rate of the cross talk noise, and determining a net connected to a output end of the cell as the net where the cross talk noise is reduced when the cross talk noise does not cause malfunction of the receiver cell and when a signal to be supplied to the receiver cell satisfies a timing constraint.

### BRIEF DESCRIPTION OF DRAWINGS

FIG. 1 is a view schematically showing a system for adjusting noise of an embodiment of the present invention.

FIG. 2 is a diagram schematically showing a logic circuit having a cross talk noise.

FIG. 3 is a graph schematically showing a voltage of the cross talk noise.

FIG. 4 is a graph schematically showing a method for calculating the voltage of the cross talk noise through a repeater.

FIG. 5 is a diagram schematically showing a logic circuit changed repeater size.

FIG. 6 is a diagram schematically showing repeater candidates insertable for reducing the cross talk noise.

FIG. 7 is a diagram schematically showing a logic circuit inserted a repeater.

FIG. 8 is a diagram schematically showing a logic circuit inserted a repeater.

FIG. 9 is a diagram schematically showing a logic circuit performed spacing of mutually adjacent wires thereof.

FIG. 10 is a flow diagram schematically showing a method for adjusting noise by resizing the cell size of an embodiment of the present invention.

FIG. 11 is a flow diagram schematically showing a method for adjusting noise by inserting the repeater of an embodiment of the present invention.

### DETAILED DESCRIPTION OF EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

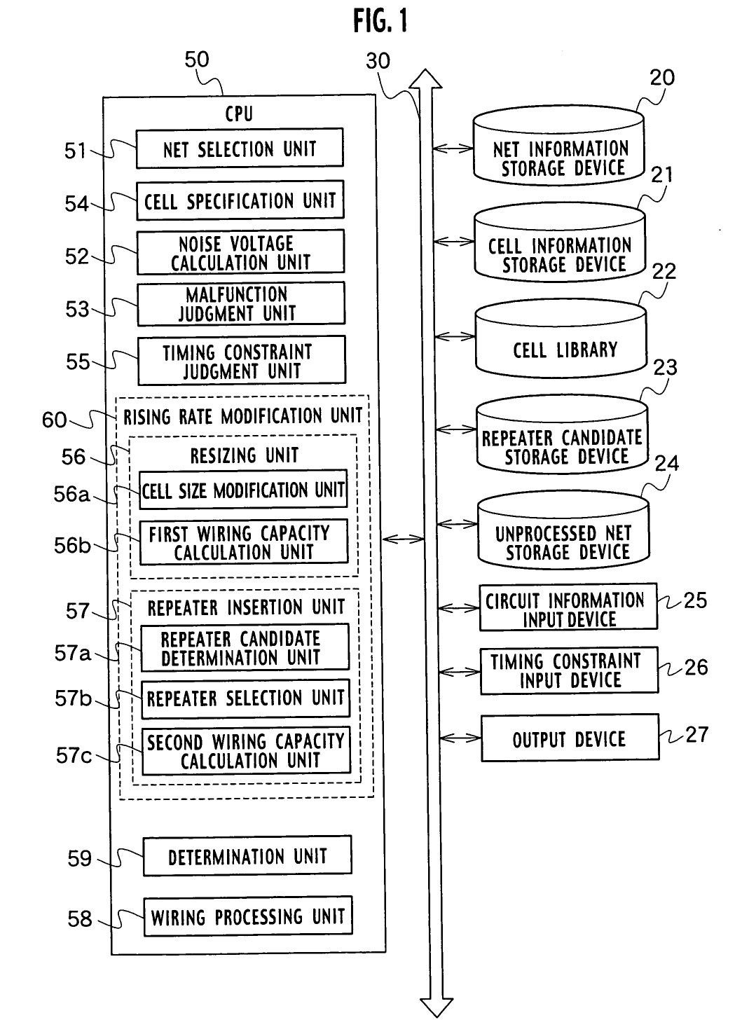

As shown in FIG. 1, a noise correction system according to an embodiment of the present invention includes a bus 30, a CPU 50 connected to the bus 30, a net information storage device 20, a cell information storage device 21, a cell library 22, a repeater candidate storage device 23, an unprocessed net storage device 24, a 25, a timing constraint input device 26, and an output device 27. The CPU 50 further includes a net selection unit 51, a cell specification unit 54, a noise voltage calculation unit 52, a malfunction judgment unit 53, a timing constraint judgment unit 55, a rise rate modification unit 60, a determination unit 59, and a wiring processing unit 58. The rise rate modification unit 60 further includes a resizing unit 56 and a repeater insertion unit 57. The resizing unit 56 further includes a cell size modification unit 56a and a first wiring capacity calculation unit 56b. The repeater insertion unit 57 further includes a repeater candidate determination unit 57a, a repeater selection unit 57b, and a second wiring capacity calculation unit 57c.

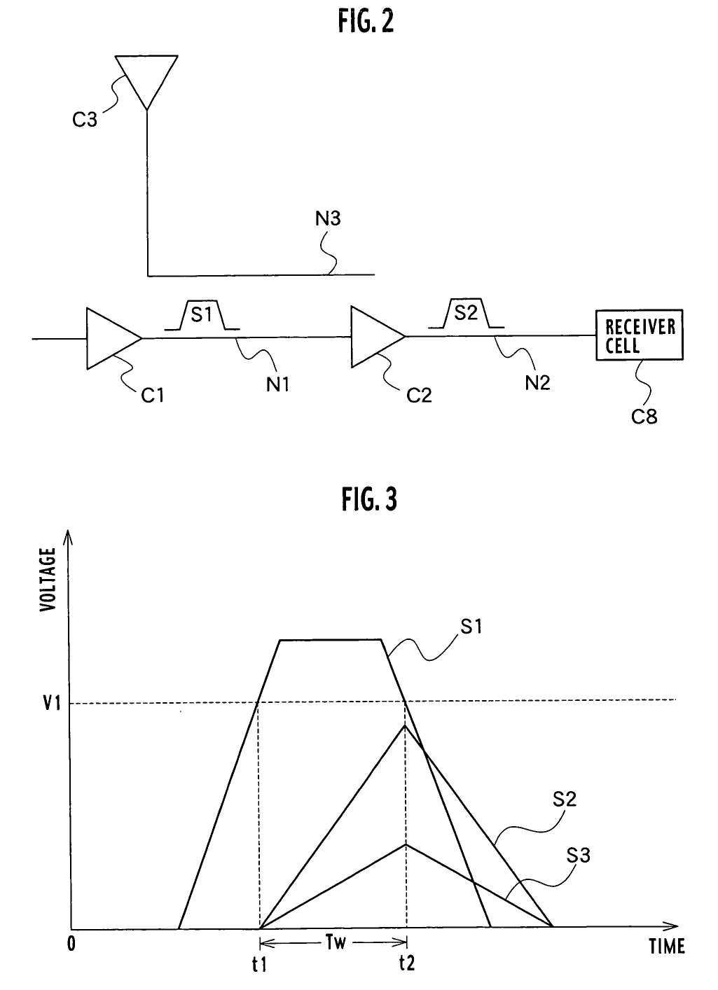

FIG. 2 shows part of a logic circuit which causes a cross talk noise. Part of a designed logic circuit includes a cell C1, a cell C2, and a receiver cell C8. The cell C1 is connected to the cell C2 by a net N1. The cell C2 is connected to the receiver cell C8 by a net N2. Moreover, part of the designed logic circuit includes a cell C3, and a net N3 is connected to an output end of the cell C3. Since the net N3 is adjacent to the net N1, a signal propagated on the net N3 causes a cross talk noise S1 on the net N1.

The cross talk noise S1 is inputted to the cell C2 and emerges on the net N2 as a cross talk noise S2.

The net information storage device 20 stores: wiring for connecting the logic circuit; connection statuses and connection paths of the wiring, in the designed logic circuit, such as clock wiring. The connection statuses of the net N1, the net N2, and the net N3, and the connection paths thereof are stored in the net information storage device 20.

The cell information storage device 21 stores types, positions, sizes, drive voltages, and capacities of cells in the designed logic circuit. For example, as shown in FIG. 2, the positions, the sizes, the drive voltages, and the capacities of the cells C1 to C3 and of the receiver cell C8 are stored in the cell information storage device 21.

The cell library 22 stores types, sizes, drive voltages, and capacities of the cells used for design.

The repeater candidate storage device 23 stores types, positions, sizes, drive voltages, and capacities of repeaters determined by the repeater candidate determination unit 57a.

The unprocessed net storage device 24 stores a position of a net where a cross talk noise causing malfunction of a logic element occurs.

The circuit information input device 25 inputs the connection statuses and the connection paths of the wiring in the designed logic circuit, and the types, the positions, the sizes, the drive voltages, and the capacities of the cells. For example, the information on the cells C1 to C3, the receiver cell C8, and the nets N1 to N3 which collectively constitute the logic circuit shown in FIG. 2 is inputted by the circuit information input device 25.

The timing constraint input device 26 inputs timing constraints, such as set-up time, hold time, and the like, of the cells in the designed logic circuit. For example, the timing constraints of the receiver cell C8 shown in FIG. 2 are inputted by the timing constraint input device 26.

The output device 27 outputs the data which are outputted from the CPU 50, and the data to be stored in the net information storage device 20, the cell information storage device 21, the cell library 22, and the repeater candidate storage device 23.

The net selection unit 51 selects an unprocessed net, which is not yet subjected to noise reduction, out of the data stored in the unprocessed net storage device 24. For example, when the net N2 shown in FIG. 2 is not yet subjected to noise reduction, the net selection unit 51 selects the net N2.

The cell specification unit 54 reads the information on the cells from the cell information storage device 21 and specifies a cell which outputs a cross talk noise to the net selected by the net selection unit 51. For example, the cell specification unit 54 specifies the cell C2 which outputs the cross talk noise S2 to the net N2 shown in FIG. 2.

FIG. 3 shows variation with time of voltages of cross talk noises occurring on the nets. The noise voltage calculation unit 52 calculates the voltages of the cross talk noises from the data on the wiring and the cells stored in the net information storage device 20 and the cell information storage device 21 by means of simulation or the like. For example, as shown in FIG. 3, the noise voltage calculation unit 52 calculates the voltage of the cross talk noise S1 occurring on the net N1 shown in FIG. 2. Moreover, the noise voltage calculation unit 52 calculates a voltage of a cross talk noise which passes through a cell (including a repeater). For example, the noise voltage calculation unit 52 calculates the voltage of the cross talk noise S2 which passes through the cell C2 shown in FIG. 2. The voltage of the cross talk noise which passes through the cell is calculated based on the size of the cell which is passed through and on the capacity of the wiring connected to an output end of the cell to be passed through. Alternatively, the voltage of the cross talk noise is calculated by a voltage required for driving the cell (hereinafter referred to as a “threshold voltage”) as well.

For example, when the threshold voltage of the cell C2 is V1 as shown in FIG. 3, the voltage of the cross talk noise S2 which passes through the cell C2 starts increasing when the voltage of the cross talk noise S1 exceeds the threshold voltage V1 (at time t1), and the voltage of the cross talk noise S2 continues to increase during a period of time Tw (Tw=t2−t1) when the voltage of the cross talk noise S1 continues to exceed the threshold voltage V1. Thereafter, the voltage of the cross talk noise S2 starts decreasing when the voltage of the cross talk noise S1 falls below the threshold voltage V1 (at time t2), and the voltage of the cross talk noise S2 continues to decrease unless the voltage of the cross talk noise S1 exceeds the threshold voltage V1. Moreover, a waveform of the cross talk noise which passes through the cell C2 is influenced by the size of the cell C2 and the wiring capacity at the output end of the cell C2. For example, a rise rate of the cross talk noise becomes slower as shown in a cross talk noise S3 in FIG. 3 as the size of the cell C2 becomes smaller. Likewise, the rise rate of the cross talk noise becomes slower as shown in the cross talk noise S3 in FIG. 3 as the wiring capacity at the output end of the cell C2 becomes larger. In this way, the rise rate of the cross talk noise is determined by the size of the cell and by the wiring capacity.

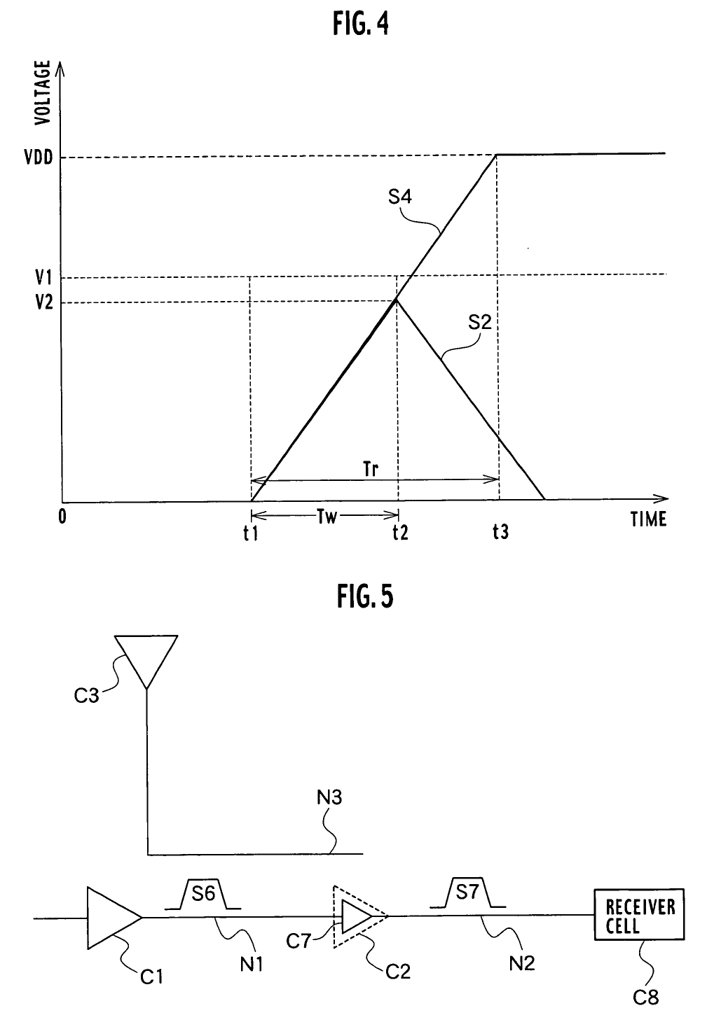

For example, as shown in FIG. 4, assuming that a rise time of a signal S4 outputted from the cell C2 and propagated on the net N2 is Tr (Tr=t3−t1) and that a power supply voltage is VDD, a rise rate of the signal S4 is equal to VDD/Tr. This rise rate of the signal S4 outputted from the cell C2 is used as the rise rate of the cross talk noise S2 which passes through the cell C2. Accordingly, a maximum voltage V2 of the cross talk noise S2 is equal to Tw·VDD/Tr.

The rise rate modification unit 60 slows down the rise rate of the cross talk noise which passes through the cell. The resizing unit 56 modifies the size of the cell which is specified by the cell specification unit 54. The cell size modification unit 56a specifies one size of the cell for modification from the cell library 22, and modifies the cell specified by the cell specification unit 54 into the specified cell size. The cell size modification unit 56a modifies the cell size so as to render the rise rate slower than that of the cell which is specified by the cell specification unit 54. For example, as shown in FIG. 5, the cell size of the cell C2 shown in FIG. 2 is modified into a cell size of a cell C7.

The first wiring capacity calculation unit 56b calculates a capacity of wiring which is connected to an output end of the cell modified by the cell size modification unit 56a. For example, in FIG. 5, the first wiring capacity calculation unit 56b calculates the wiring capacity of the net N2 connected to the output end of the cell C7 which is modified by the cell size modification unit 56a.

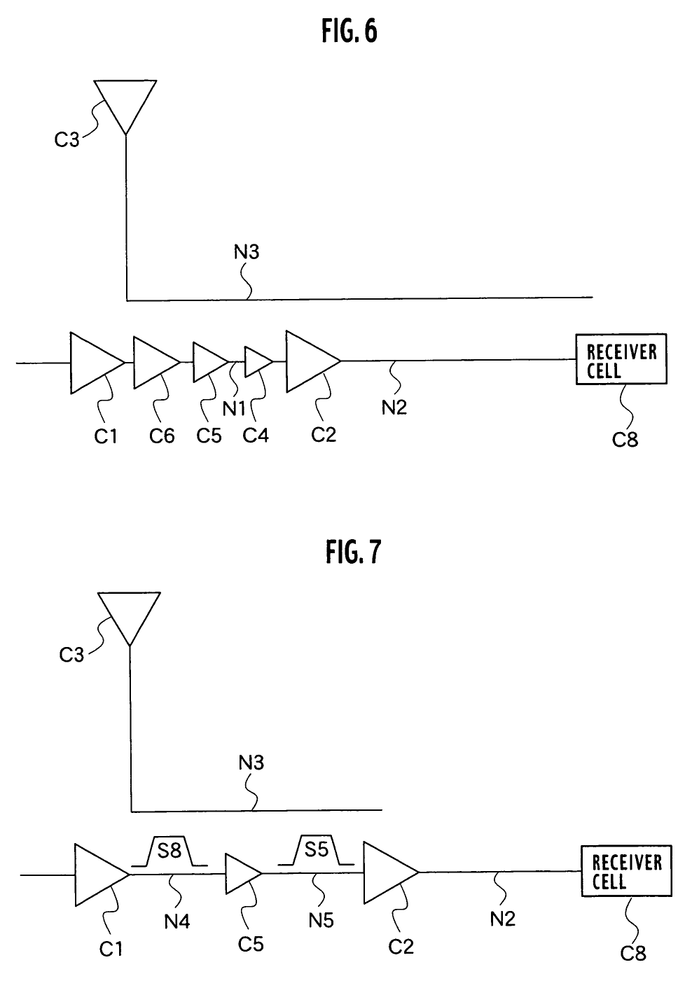

The repeater insertion unit 57 inserts a repeater, which has a slower rise rate than the cell specified by the cell specification unit 54, into a net at an input end of the specified cell. FIG. 6 illustrates repeater candidates (repeaters C4 to C6) insertable for reducing the cross talk noise S1 occurring on the net N1 shown in FIG. 2. A possibility of insertion is determined based on whether or not an insertion area is secured and whether or not wiring required for an inserted repeater is secured. The repeater candidate determination unit 57a reads the data on the wiring and the cells from the net information storage device 20 and the cell information storage device 21, and then determines positions and sizes of all the repeaters which can be inserted to the net where the cross talk noise occurs, based on a congestion degree of the wiring and density of the cells. For example, as shown in FIG. 6, the repeater candidate determination unit 57a determines the positions and the sizes of the repeaters C4 to C6 which can be inserted to the net N1. The repeater selection unit 57b selects one of the repeaters which are determined by the repeater candidate determination unit 57a, and inserts the selected repeater to the net. The repeater selection unit 57b inserts the repeater, which has a slower rise rate than the repeater specified by the cell specification unit 54, to the net at the output end of the specified repeater. For example, as shown in FIG. 7, the repeater selection unit 57b selects the repeater C5 out of the candidates shown in FIG. 6, and the repeater C5 is inserted to the net N1 as shown in FIG. 6. In this case, as shown in FIG. 7, the cell C1 is connected to the repeater C5 by a net N4, and the repeater C5 is connected to the cell C2 by a net N5.

The second wiring capacity calculation unit 57c calculates a capacity of wiring connected to an output end of the repeater which is inserted by the repeater selection unit 57b. For example, when the repeater C5 is inserted by the repeater selection unit 57b as shown in FIG. 7, the second wiring capacity calculation unit 57c calculates the wiring capacity of the net N5.

The malfunction judgment unit 53 judges whether or not the cross talk noise causes malfunction of the receiver cell, based on the voltage of the cross talk noise which is calculated by the noise voltage calculation unit 52. For example, the malfunction judgment unit 53 judges whether or not a cross talk noise S7 shown in FIG. 5 causes malfunction of the receiver cell C8. Alternatively, the malfunction judgment unit 53 judges whether or not a cross talk noise S5 shown in FIG. 7 causes malfunction of the cell C2.

The timing constraint judgment unit 55 judges whether or not a signal to be inputted to the cell satisfies the timing constraints and the like which are inputted by the timing constraint input device 26. For example, the timing constraint judgment unit 55 judges whether or not a signal outputted from the cell C7 shown in FIG. 5 or a signal outputted from the repeater C5 shown in FIG. 7 satisfies the set-up time and the hold time at the receiver cell C8 shown in FIG. 5 or at the cell C2 shown in FIG. 7.

When the receiver cell to which the cross talk noise is inputted does not suffer malfunction attributable to the cross talk noise, and when the signal to be inputted to the receiver cell satisfies the timing constraints of the receiver cell, the determination unit 59 determines the net connected to the output end of the cell specified by the cell specification unit 54 as the net where the cross talk noise is reduced. To be more precise, when the cross talk noise passing through the cell modified by the cell size modification unit 56a does not cause malfunction of the receiver cell, and when the signal to be inputted to the receiver cell satisfies the timing constraints, the determination unit 59 allows the cell information storage device 21 to store the cell size of the cell modified by the cell size modification unit 56a, and determines the net to be connected to the output end of the modified cell as the net where the cross talk noise is reduced. Moreover, when the cross talk noise passing through the repeater inserted by the repeater selection unit 57b does not cause malfunction of the receiver cell, and when the signal to be inputted to the receiver cell satisfies the timing constraints, the determination unit 59 allows the cell information storage device 21 to store the position and the size of the repeater selected by the repeater selection unit 57b, and determines the net to be connected to the output end of the selected repeater as the net where the cross talk noise is reduced.

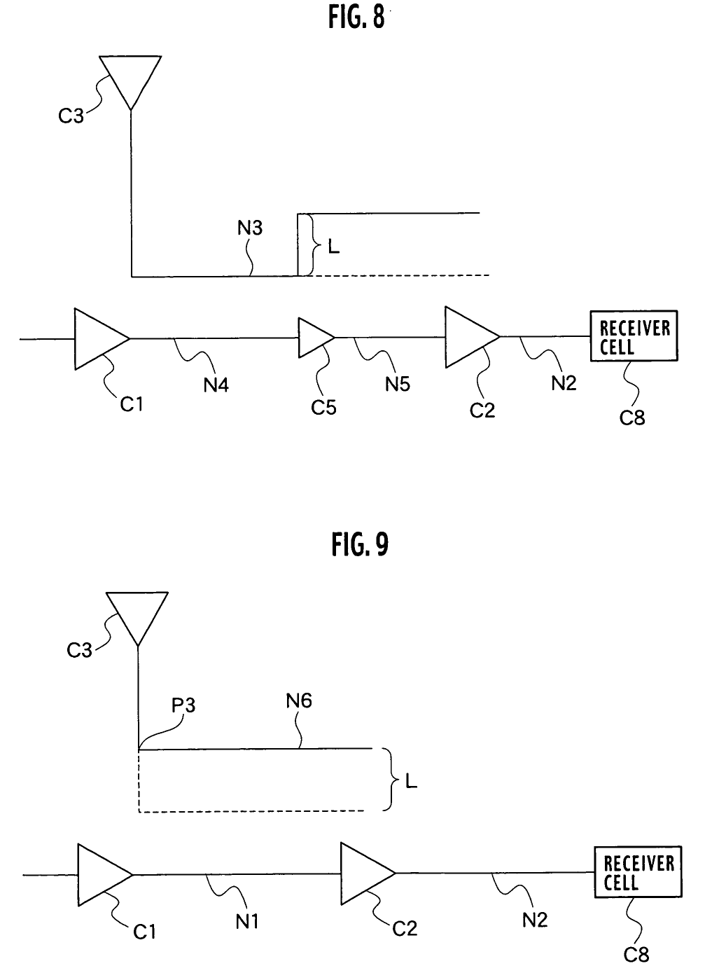

The wiring processing unit 58 performs spacing of mutually adjacent wires. The “spacing” is to extend an interval between the adjacent wires for reducing the cross talk noise. For example, as shown in FIG. 8, a wire of the net N3 adjacent to the net N5 shown in FIG. 7 is wired so as to be shifted from a point P1 by an interval L with its continuity. Alternatively, as shown in FIG. 9, the wire of the net N3 adjacent to the net N1 connected to the output end of the cell C1 shown in FIG. 2 is wired so as to be shifted from a point P3 by an interval L with its continuity. Then, the wiring processing unit 58 allows the net information storage device 20 to store wiring path data subjected to the spacing.

According to the noise correction system of the embodiment of the present invention, it is possible to reduce the cross talk noise without extending the interval between the wires or inserting the repeater, but by means of adjusting the cell size of the existing cell. Moreover, it is possible to further reduce the cross talk noise by adjusting the repeater size of the inserted repeater cell. As a result, the cross talk noise is reduced in an area congested with wiring and the number of repeaters for insertion is reduced as well. Accordingly, it is possible to achieve large-scale integration while reducing the cross talk noises.

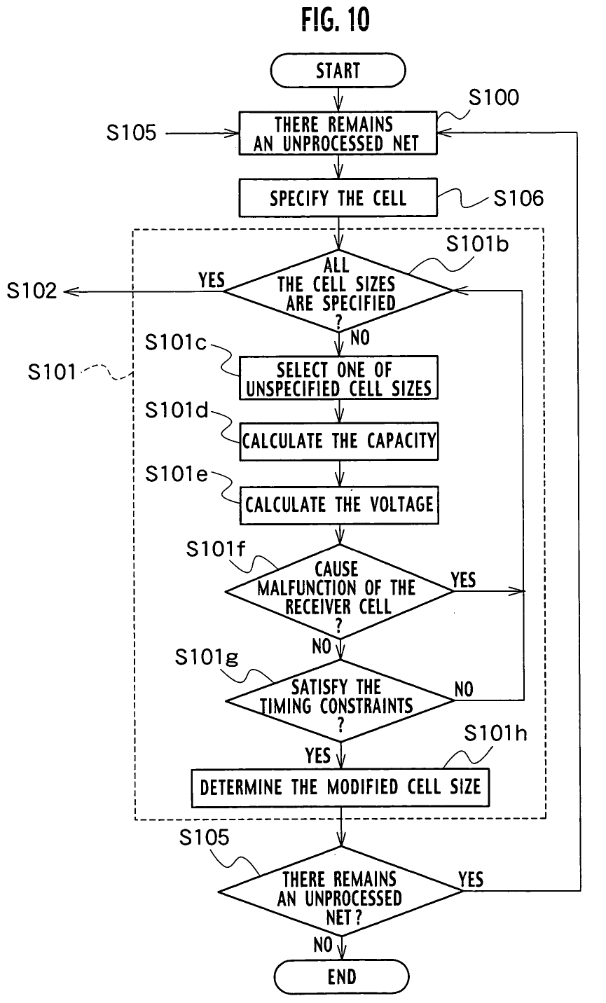

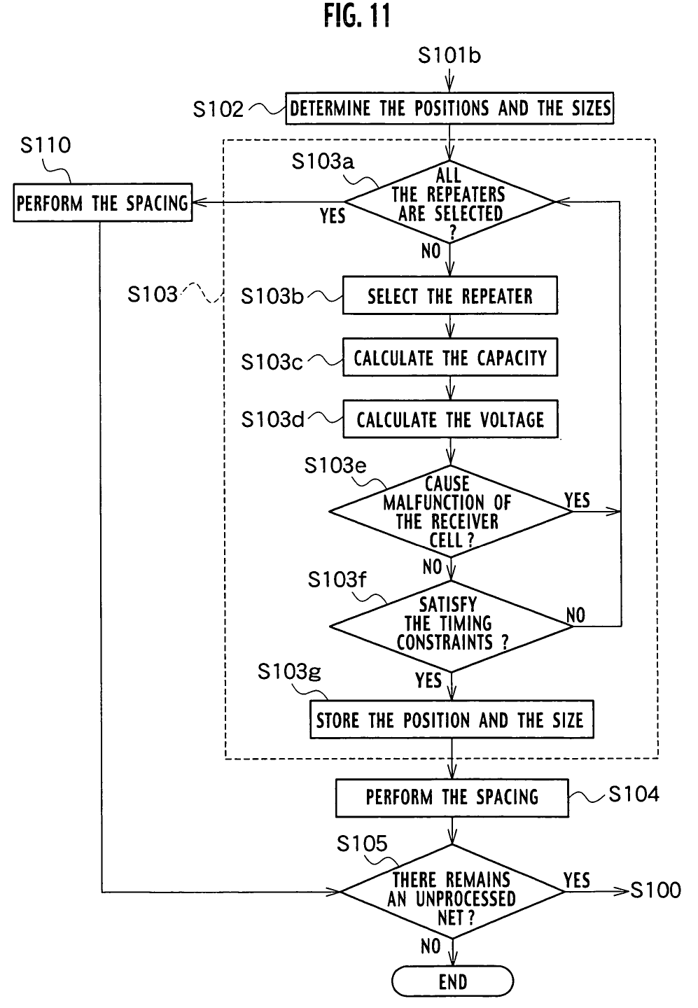

Next, a noise reduction method according to the embodiment of the present invention will be described with reference to FIG. 10 and FIG. 11.

(a) In Step S100 of FIG. 10, the net selection unit 51 shown in FIG. 1 selects the unprocessed net out of the data stored in the unprocessed net storage device 24. The size of the repeater is modified in Step S101.

(b) Specifically, in Step S106, the cell specification unit 54 specifies the cell which outputs the cross talk noise to the net selected by the net selection unit 51. In Step S101b, the cell size modification unit 56a judges whether or not all the cell sizes stored in the cell library 22 are specified. When all the cell sizes are specified, the process moves to Step S102. When all the cell sizes are not specified yet, the process moves to Step S101c. In Step S101c, the cell size modification unit 56a selects one of unspecified cell sizes from the cell library 22. Then, the cell size modification unit 56a modifies the cell size so as to render the rise rate slower than that of the cell which is specified by the cell specification unit 54. The cell size modification unit 56a modifies the cell C2 shown in FIG. 2 into the cell C7 as shown in FIG. 5. In Step S101d, the first wiring capacity calculation unit 56b calculates the capacity of the wiring connected to the output end of the cell modified by the cell size modification unit 56a.

In Step S101e, the noise voltage calculation unit 52 calculates the voltage of the cross talk noise which passes through the cell (including the repeater). In FIG. 5, the noise voltage calculation unit 52 calculates the voltage of a cross talk noise S6 propagated on the net N1. Moreover, the noise voltage calculation unit 52 calculates the voltage of the cross talk noise S7 which passes through the cell C2. In Step S101f, the malfunction judgment unit 53 judges whether or not the cross talk noise causes malfunction of the receiver cell, based on the voltage of the cross talk noise passing through the cell modified by the cell size modification unit 56a. In FIG. 5, the malfunction judgment unit 53 judges whether or not the cross talk noise S7 passing through the cell C2 causes malfunction of the receiver cell C8 connected to the output end of the cell C2. When the cross talk noise causes malfunction of the receiver cell, the process returns to Step S101b and a new cell size is specified by the cell size modification unit 56a in Step S101c.

When the cross talk noise does not cause malfunction of the receiver cell, then in Step S101g, the timing constraint judgment unit 55 judges whether or not the receiver cell satisfies the timing constraints and the like which are inputted by the timing constraint input device 26. In FIG. 5, the timing constraint judgment unit 55 judges whether or not the signal outputted from the cell C2 satisfies the timing constraints of the receiver cell C8. When the timing constraints are not satisfied, the process returns to Step S101b and a new cell size is specified by the cell size modification unit 56a in Step S101c. When the timing constraints are satisfied, then in Step S101h, the determination unit 59 determines the modified cell size as the cell size of the specified cell. Then, the determination unit 59 allows the cell information storage device 21 to store the modified cell size, and determines the net to be connected to the output end of the modified cell as the net where the cross talk noise is reduced. Thereafter, the process moves to Step S105.

(c) In Step S105, the net selection unit 51 judges whether or not there remains an unprocessed net not yet subjected to noise reduction, based on the data stored in the unprocessed net storage device 24. When there is an unprocessed net not yet subjected to noise reduction, the process returns to Step S100 and the unprocessed net not yet subjected to noise reduction is selected. When there is no unprocessed net not yet subjected to noise reduction, all noise reduction is deemed to be completed and is therefore terminated.

(d) In Step S101b shown in FIG. 10, if it is not possible to reduce the cross talk noise in spite of specifying all the cell sizes, then in Step S102 shown in FIG. 11, the repeater candidate determination unit 57a determines the positions and the sizes of all repeaters which are insertable to the net N1 as shown in FIG. 6 where the cross talk noise shown in FIG. 2 occurs. In Step S103, a repeater is inserted to the net where the cross talk noise occurs.

(e) Specifically, in Step S103a, the repeater selection unit 57b judges whether or not all the repeaters determined by the repeater candidate determination unit 57a are selected. When all the repeaters are not selected yet, then in Step S103b, the repeater selection unit 57b selects the repeater having a slower rise rate than the repeater specified by the cell specification unit 54, and inserts the selected repeater to the net at the input end of the specified repeater. In Step S103c, the second wiring capacity calculation unit 57c calculates the capacity of the wiring to be connected to the output end of the repeater inserted by the repeater selection unit 57b. In Step S103d, the noise voltage calculation unit 52 calculates the voltage of the cross talk noise passing through the repeater. For example, when the repeater C5 shown in FIG. 6 is selected by the repeater selection unit 57b and is inserted between the net N4 and the net N5 as shown in FIG. 7, the noise voltage calculation unit 52 calculates a voltage of a cross talk noise S8 occurring on the net N4. Moreover, the noise voltage calculation unit 52 calculates the voltage of the cross talk noise S5 passing through the repeater C5. In Step S103e, the malfunction judgment unit 53 judges whether or not the cross talk noise causes malfunction of the receiver cell, based on the voltage of the cross talk noise passing through the repeater. As shown in FIG. 7, the malfunction judgment unit 53 judges whether or not the cross talk noise S5 passing through the cell C5 causes malfunction of the cell C2. When the cross talk noise causes malfunction of the receiver cell, the process returns to Step S103a and a new repeater is inserted by the repeater selection unit 57b in Step S103b.

When the cross talk noise does not cause malfunction of the receiver cell, then in Step S103f, the timing constraint judgment unit 55 judges whether or not the receiver cell satisfies the timing constraints and the like which are inputted by the timing constraint input device 26. As shown in FIG. 7, the timing constraint judgment unit 55 judges whether or not the signal outputted from the repeater C5 satisfies the timing constraints of the receiver cell C8. When the timing constraints are not satisfied, the process returns to Step S103a and a new repeater is inserted by the repeater selection unit 57b in Step S103b. When the timing constraints are satisfied, then in Step S103g, the determination unit 59 allows the cell information storage device 21 to store the position and the size of the repeater selected by the repeater selection unit 57b, and then determines the net connected to the output end of the selected repeater and the net connected to the output end of the cell specified by the cell specification unit 54 as the nets where the cross talk noises are reduced. Thereafter, the process moves to Step S104. In Step S104, the wiring processing unit 58 performs the spacing in terms of the wiring which is adjacent to the wiring connected to the output end of the inserted repeater. The wiring of the net N3 adjacent to the net N5 connected to the output end of the repeater C5 shown in FIG. 7 is wired so as to be shifted from the point P1 by the interval L with its continuity as shown in FIG. 8.

(f) In Step S103a, if it is not possible to reduce the cross talk noise in spite of specifying all the repeaters, then in Step S110, the wiring processing unit 58 performs the spacing of the wiring adjacent to the net where the cross talk noise occurs. As shown in FIG. 9, the wiring of the net N3 adjacent to the net N1 connected to the output end of the cell C1 shown in FIG. 2 is wired so as to be shifted from the net N1 by the interval L with its continuity as shown in a net N6. Then, the process moves to Step S105.

(g) In Step S105, the net selection unit 51 judges whether or not there remains an unprocessed net not yet subjected to noise reduction, based on the data stored in the unprocessed net storage device 24. When there is an unprocessed net not yet subjected to noise reduction, the process returns to Step S100 and the unprocessed net not yet subjected to noise reduction is selected. When there is no unprocessed net not yet subjected to noise reduction, all noise reduction is deemed to be completed and is therefore terminated.

According to the noise reduction method of the embodiment of the present invention, it is possible to reduce the cross talk noise without spreading the space between the wires or inserting the repeater, but by means of adjusting the cell size of the existing cell. Moreover, it is possible to further reduce the cross talk noise by adjusting the repeater size of the inserted repeater cell. As a result, the cross talk noise is reduced in an area congested with wiring and the number of repeaters for insertion is reduced as well. Accordingly, it becomes possible to achieve large-scale integration while reducing the cross talk noises.

Various modifications will become possible for those skilled in the art after receiving the teachings of the present disclosure without departing from the scope thereof.

1. A system for adjusting noise comprising:
a cell specification unit configured to specify a cell which transmits a cross talk noise to a receiver cell;
a rise rate modification unit configured to slow down a rise rate of the cross talk noise; and
a determination unit configured to determine a net connected to a output end of the cell as the net where the cross talk noise is reduced when the cross talk noise does not cause malfunction of the receiver cell, and when a signal to be supplied to the receiver cell satisfies a timing constraint.

2. The system of claim 1, wherein the rise rate modification unit has a resizing unit configured to modify a size of the cell to slow down a rise rate of the cross talk noise.

3. The system of claim 2, wherein the resizing unit has a cell size modification unit configured to specify one size of the cell for modification and modify the cell into the specified cell size so as to render the rise rate slower than the rise rate of the cell.

4. The system of claim 3, wherein the resizing unit has a first wiring capacity calculation unit configured to calculate a capacity of wiring connected to an output end of the modified cell.

5. The system of claim 1, wherein the rise rate modification unit has a repeater insertion unit inserts a repeater having a slower rise rate than a rise rate of the cell into a net connected to an input end of the specified cell.

6. The system of claim 2, wherein the rise rate modification unit has a repeater insertion unit inserts a repeater having a slower rise rate than a rise rate of the cell into a net connected to an input end of the specified cell.

7. A method for adjusting noise comprising:
specifying a cell which transmits a cross talk noise to a receiver cell;
slowing down a rise rate of the cross talk noise; and
determining a net connected to a output end of the cell as the net where the cross talk noise is reduced when the cross talk noise does not cause malfunction of the receiver cell, and when a signal to be supplied to the receiver cell satisfies a timing constraint.

8. The method of claim 7, wherein the slowing down a rise rate comprises:
modifying a size of the cell to slow down a rise rate of the cross talk noise.

9. The method of claim 8, wherein the modifying the size of the cell comprises:
specifying one size of the cell for modification; and
modifying the cell into the specified cell size so as to render the rise rate slower than the rise rate of the cell.

10. The method of claim 9, wherein the modifying the size of the cell comprises:
calculating a capacity of wiring connected to an output end of the modified cell.

11. The method of claim 7, wherein the slowing down a rise rate comprises:
inserting a repeater having a slower rise rate than the cell, into a net connected to an input end of the specified cell.

12. The method of claim 8, wherein the slowing down a rise rate comprises:
inserting a repeater having a slower rise rate than the cell, into a net connected to an input end of the specified cell.
